(19) United States
(12) Patent Application Publication
(10) Pub. No.: US 2014/0225590 A1
(43) Pub. Date: Aug. 14, 2014

(54) METHOD AND SYSTEM FOR IMPLEMENTING REMOTE SPECTRUM ANALYSIS

(71) Applicant: Arinc Incorporated, (US)

(72) Inventor: Michael W. JACOBS, Annapolis, MD (US)

(73) Assignee: ARINC INCORPORATED, Annapolis, MD (US)

(21) Appl. No.: 13/745,728

(22) Filed: Jan. 18, 2013

Related U.S. Application Data
(60) Provisional application No. 61/588,760, filed on Jan. 20, 2012.

(51) Int. Cl. G01R 23/16

(52) U.S. Cl. CPC G01R 23/16
USPC 324/76.19

(57) ABSTRACT

A system and method are provided that advantageously combine Commercial-off-the shelf hardware and software components in a portable, ruggedized package for remotely monitoring radio-frequency (RF) spectrum activity with regard to a specific platform, structure or location for an extended duration. Provisions are made for remote access to, and analysis of, monitored spectrum activity data. The disclosed systems and methods evaluate spectrum usage over time, facilitate management and enforcement of spectrum allocations and restrictions, conduct extended spectrum surveillance, and analyze interference without on-site user involvement. RF spectrum analyzers, are connected to an onboard computer processing capacity, an integrated power supply, network backhaul connectivity components, and onboard diagnostic capabilities to support the remote unattended operation of the package. Data analysis components in communication with the remote package are used to generate custom graphs and reports for data reduction.

This application claims priority to U.S. Provisional Patent Application No. 61/588,760, entitled “Method And System For Remote Spectrum Analysis,” filed on Jan. 20, 2012.

### BACKGROUND

1. Field of the Disclosed Embodiments

This disclosure relates to methods and systems for implementing and/or facilitating extended duration remote spectrum analysis.

2. Related Art

With the proliferation of all forms of radio and wireless telecommunications using different portions of the radio-frequency (RF) spectrum, it can be difficult to predict the propagation of the RF energy emanating from any given source, particularly a source that emanates RF energy from a number of components across a broad spectrum of RF frequencies. There is also often a requirement, in view of situations where multiple RF radiation sources are essentially co-located to detect the presence of interfering signals between the multiple RF radiation sources. This task can be which can be equally difficult to predicting propagation.

Based on a number of factors, RF radiation patterns tend to be irregular and unpredictable. In order to assess detectability of a particular group of radiation sources, and/or to achieve optimal reliability and throughput for the varied RF radiation sources in the group, it is often appropriate to detect and identify RF radiation sources, and to discern sources of interference that may affect the performance of the detected RF radiation sources.

Real world targets for assessing RF spectrum activities include conventional aircraft or other transportation platforms. These platforms tend to have a number of voice and data radios associated with them and they tend to provide a relatively limited body structure to support, for example, optimal placement of various antennas to mitigate mutual interference between RF signals received by or transmitted from the various radios. RF spectrum analysis for these platforms can be particularly necessary and beneficial.

Spectrum usage for any platform or co-located group of RF sources necessarily varies with time. As a result, spectrum usage measurements made at any one instant likely do not reflect a full scope of spectrum conditions experienced on a particular platform or at a particular location where a number of RF sources are operating. Extended monitoring over periods ranging from hours to days to weeks, with limited delay times between monitored RF usage data samples, including virtual continuous monitoring, are generally considered appropriate depending on the detail required in a resultant spectrum analysis to attempt to capture and characterize a full scope of spectrum activity. Intermittent problems, which may include, but are not limited to, interference due to intermodulation or anomalous RF propagation, occur at seemingly random times. These problems introduce variations in the spectrum usage that are difficult to capture with just a snapshot set of measurements or even during a site visit of limited duration.

### SUMMARY OF THE DISCLOSED EMBODIMENTS

In view of the increase in RF spectrum usage, the need to be able to accurately characterize that spectrum usage to a number of beneficial purposes, and in view of the shortfalls encountered in short-duration monitoring, it would be advantageous to provide a simple means by which to effect extended monitoring of spectrum conditions with regard to a particular platform, structure or geographic location. This simple means should implement collection of RF spectrum usage data over extended periods of time in a manner that does not require significant user effort or on-site presence of monitoring or support personnel.

Exemplary embodiments of the disclosed systems and methods may provide an ability to remotely monitor RF spectrum activity for an extended duration.

Exemplary embodiments may provide hardware and/or software components that facilitate the remote monitoring of unattended RF spectrum analyzers and that additionally provide ready access to, and analysis of, monitored spectrum activity data.

Exemplary embodiments may prove useful in (1) evaluating spectrum usage, (2) managing and enforcing spectrum allocations, (3) conducting spectrum surveillance, and (4) analyzing spectral interference.

Exemplary embodiments may be used as a data input source for a spectrum activity database or, for example, for a Spectrum Common Operating Picture (S-COP).

In exemplary embodiments, system components may be mounted in ruggedized portable cases, such as portable rugged Pelican® cases, making them portable and robust.

Exemplary embodiments may employ relatively inexpensive Commercial-off-the-shelf (COTS RF) spectrum analyzers, which may be supported by local processors or onboard computing devices, integrated power supplies, network backhaul components and/or onboard diagnostic devices, all of which are intended to facilitate remote autonomous unattended operation for the spectrum activity measurement system.

Exemplary embodiments may support other electronic equipment such as receivers or transceivers for remote operations using, for example, voice/radio over IP technology over a provided backhaul channel, and some manner of positioning reference, such as a Global Positioning Satellite (GPS) system receiver for localizing a position of the system when field deployed as a fixed or mobile monitoring unit.

In embodiments, in addition to portable hardware components or systems, data analysis software may be used, locally or remotely, to generate custom outputs including graphs and reports that may be representative of, or used for, data reduction.

These and other features, and advantages, of the disclosed systems and methods are described in, or apparent from, the following detailed description of exemplary embodiments.

### BRIEF DESCRIPTION OF THE DRAWINGS

Various exemplary embodiments of the disclosed methods and systems for implementing and/or facilitating extended duration remote spectrum analysis according to this disclosure will be described, in detail, with reference to the following drawings, in which:

FIG. 1 illustrates a schematic diagram of a general configuration for a network operating environment in which the systems and methods according to this disclosure may be operated for conducting extended duration remote spectrum analysis;

FIG. 2 illustrates a block diagram of an exemplary system for conducting extended duration remote spectrum analysis according to this disclosure; and

FIG. 3 illustrates a flowchart of an exemplary method for conducting extended duration remote spectrum analysis according to this disclosure.

### DESCRIPTION OF THE DISCLOSED EMBODIMENTS

The disclosed systems and methods for implementing and/or facilitating extended duration remote spectrum analysis according to this disclosure may discuss such a particular implementation for the disclosed systems and methods. References to either or both of a particular physical structure or a particular operational implementation for a particular embodiment of a portable Remote Spectrum Analysis System (RSAS) unit may be made throughout this disclosure for clarity, conciseness and understanding of a single implementation for the disclosed embodiments, concepts and schemes. These references should be considered, however, as exemplary only and not limiting, in any way to the disclosed systems and methods. In particular, the principles incumbent in the disclosed schemes for implementing and/or facilitating extended duration remote spectrum analysis may be subject to wide variation in both physical construct and operational implementation.

Specific reference to, for example, any particular monitored vehicle or platform should also be understood as being exemplary only, and not limited, in any manner, to any particular class of vehicles for travel on ground, by rail, in the air, on the sea, or under the sea. The systems and methods according to this disclosure may have been developed as being particularly adaptable to monitoring spectrum usage emanating from, or in the vicinity of, a conventional aircraft. Virtually any target, however, including any land, sea, subsea, air or space vehicle, or a particular geographic location or structure, with multiple installed RF radiation sources that may benefit from analysis of spectrum usage according to the disclosed schemes are contemplated.

Individual features and advantages of the disclosed systems and methods will be set forth in the description that follows, and will be, at least in part, obvious from the description, or may be learned by practice of the features described in this disclosure. The features and advantages of the systems and methods according to this disclosure may be realized and obtained by means of the individual elements, and combinations of those elements, as particularly pointed out in the appended claims. While specific implementations are discussed, it should be understood that this is done, as detailed above, for clarity and illustration purposes only. A person skilled in the relevant art will recognize that other components and configurations may be used without departing from the spirit and scope of the subject matter of this disclosure.

In embodiments, the disclosed system includes hardware and software components that provide an ability to remotely monitor RF spectrum activity for an extended duration and to access and analyze the resulting data. The disclosed systems and schemes may prove useful in evaluating spectrum usage, managing and enforcing spectrum allocations, conducting spectrum surveillance, and analyzing interference. Data recovered according to the disclosed systems and methods may be used as data input sources for one or more spectrum activity databases, or for a Spectrum Common Operational Picture (S-COP).

A prototype system was successfully deployed to a site where shared use of the UHF television band was proposed for a public safety land mobile radio system. It was recognized that, with respect to the target location, a potential for enhanced tropospheric propagation may lead to interference in the proposed public safety land mobile radio system from distant television transmitters. The prototype spectrum analysis system was deployed and operated over a period of months to determine a statistical likelihood of interference and to identify diurnal patterns of interference due to solar heating of the atmosphere. The collected information was used to make system design and operational decisions for the proposed public safety land mobile radio system to ensure compatibility of the proposed public safety land mobile radio system installation with the prevailing RF spectrum footprint for the target location.

The disclosed systems and methods for spectrum analysis may allow engineers or technicians to make a single site visit for spectrum analysis system deployment, and then provide remote reception of the measurement data for review. Alternately, in instances where network access may not be available (or desirable), the measurement data may be accumulated in a data storage device in the deployed spectrum analysis system package to be later collected manually from the package.

The disclosed systems and methods for spectrum analysis may be usable to record spectrum usage for regulatory or licensing purposes, to conduct traffic or channel occupancy measurements or to collect data for other like spectrum usage analysis. Information on channel loading that may be provided may include, for example, a percentage of time in a specified time period that a particular channel is occupied, a number of transmissions on a particular channel in a specified time period, an average duration for a transmissions on a particular channel, identification of a peak busy period for a particular channel, and other information for like traffic analysis for a particular channel.

The disclosed spectrum analysis system may be usable to determine whether unauthorized use of particular frequencies is occurring and when, in order that, for example, enforcement can be targeted at the times that offenders are most likely to conduct unauthorized operations.

Under the disclosed spectrum analysis schemes, monitoring of transmitted signals over time is effected so that anomalies can be detected, regulatory compliance proved and the like. Outputs from, for example, one or more multi-transmitter combiners may be sampled to observe passive intermodulation, or continuous monitoring of digital ATSC television transmissions, or the like to ensure that occupied bandwidth limits are not exceeded.

The disclosed spectrum analysis systems generally employ COTS spectrum analyzers to conduct the spectrum activities measurements generally ensuring traceability according to National Institute of Standards and Technology (NIST) standards. NIST-traceable calibrated instruments generally assure that the results of the system spectrum activities measurements may be used to demonstrate regulatory or customer compliance meeting ISO 9001 and other quality standards.

Military and law enforcement personnel may be provided a mechanism by which to observe persons or groups of interest based on an RF footprint. For military purposes, the disclosed spectrum analysis system may be used to observe friendly, enemy, or local noncombatant individual's and groups' use of the RF spectrum over time without tying up expensive Electronic Warfare (EW) assets such as full scale Electronic Support Measures (ESM) surveillance assets or systems. The disclosed integrated package may be employed to monitor spectrum on the move or stationary, and to provide near real time monitoring, or collection of historical measurement data for later analysis.

The disclosed spectrum analysis system may support a frequency assignment process by verifying that presumably vacant frequencies are, in fact, unused and free of interference, or that assigned frequencies are being used.

Based on the portability of the disclosed spectrum analysis systems and schemes, drive test surveys may be conducted using the disclosed spectrum analysis systems for coverage verification or to determine ranges of target system operations. Integrated electronic position references devices included as part of the integrated package, such as a Global Positioning Satellite (GPS) system receiver, may be usable to provide time and location information for each spectrum activity measurement generated by the spectrum analysis system.

Embodiments may include multiple antennas and an ability to select among those multiple antennas. In this manner, the systems may be used for direction finding of specific signal emitters.

Monitoring of a deployed package may be supported by the inclusion of one or more external communications interfaces, or network backhaul components. Information transmitted from the deployed spectrum analysis system package, i.e., the backhaul, may be encrypted and transmitted over commercial channels, or may use specialized or secure communication protocols or channels, including SIPR or NIPR, or other military networks. The spectrum analysis system may be configured to meet general Information Assurance (IA) compliance requirements, as needed, and may adapted to meet specific agency or user-specified IA requirements.

The disclosed spectrum analysis system may generally include two principal components system components: at least one Remote Spectrum Analysis System (RSAS) and a Spectrum Data Analysis Software (SDAS) Device.

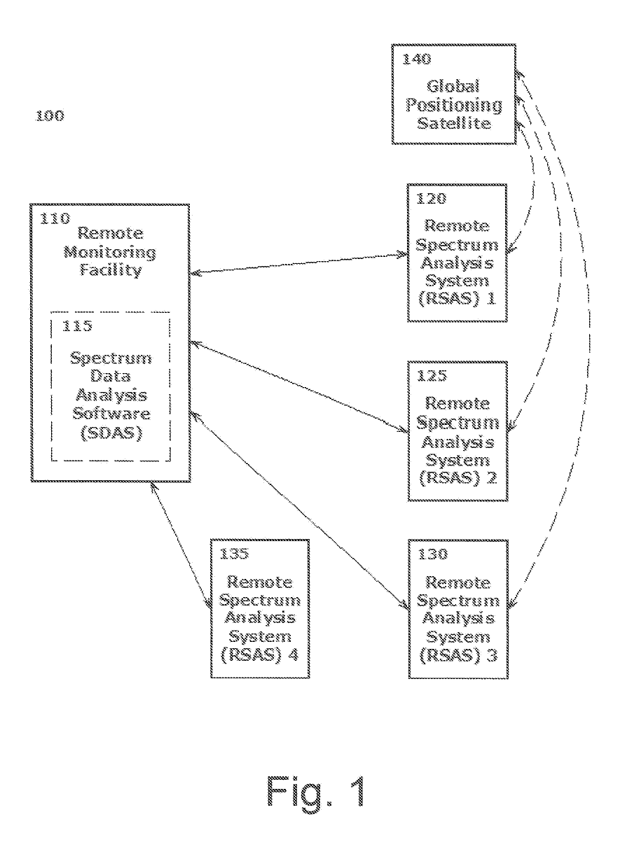

FIG. 1 illustrates a schematic diagram of a general configuration 100 for a network operating environment in which the systems and methods according to this disclosure may be operated for conducting extended duration remote spectrum analysis.

As shown in FIG. 1, one or more RSASs 1-4 120-135 may be independently deployed to monitor RF spectrum activities and characteristics of a particular platform, structure or geographic location. A detailed configuration of the elements included in each RSAS 1-4 120-135 will be discussed in greater detail below. As an overview in each RSAS 1-4 120-135 may be housed in a ruggedized case, such as a Pelican® case, or optional rack mount enclosure, in order that it may be easily deployed anywhere in the world. Each RSAS 1-4 120-135 may be deployed in a fixed or mobile configuration and placed in proximity to a target platform, structure or location for which spectrum activity measurements are to be taken and collected. Each RSAS 1-4 120-135 is generally intended to be configured to support autonomous or unattended remote spectrum activity measurement operations for extended periods of time.

Each RSAS 1-4 120-135 may be small enough to be carried as carry-on baggage, but is also ruggedized for carriage as checked baggage, or by air freight or parcel delivery. The case of the RSAS 1-4 120-135 serves as a functional “cocoon” that provides integrated power, control, and data backhaul services to an item of test equipment so that the RSAS 1-4 120-135 can function in a variety of environments with different levels of operator involvement ranging from attended operation to fully autonomous remote and unattended operation.

In embodiments, the RSAS 1-4 120-135 may (see RSAS 1-3) or may not (see RSAS 4) communicate with one or more GPS system satellites 140 to provide, for example, localization for a geographic position of the RSAS 1-3 120-130 in operation. Other geo-location methods and systems may also be used.

At least one RSAS 1-4 120-135 may be in communication with a remote monitoring facility 110 for data collect and analysis. There is no particular configuration to the remote monitoring facility 110. The remote monitoring facility 110 may range in size and sophistication from of a single user workstation to a large data collection and analysis center. The remote monitoring facility 110 is intended to provide a platform to host the SDAS 115. The SDAS 115 is an application located on a PC convenient to a user that is generally intended to be located remotely from the deployed RSASs 1-4 120-135. The SDAS 115 may be operated from, for example, a user's computer workstation, desktop computer or laptop computer. For large scale operations, a separate FTP server may be used to serve as the collection point for data from multiple remote RSAS units. For small scale operations, the SDAS PC can be used to manually collect data in wired or wireless communication with the RSAS units when the user is in close proximity thereto.

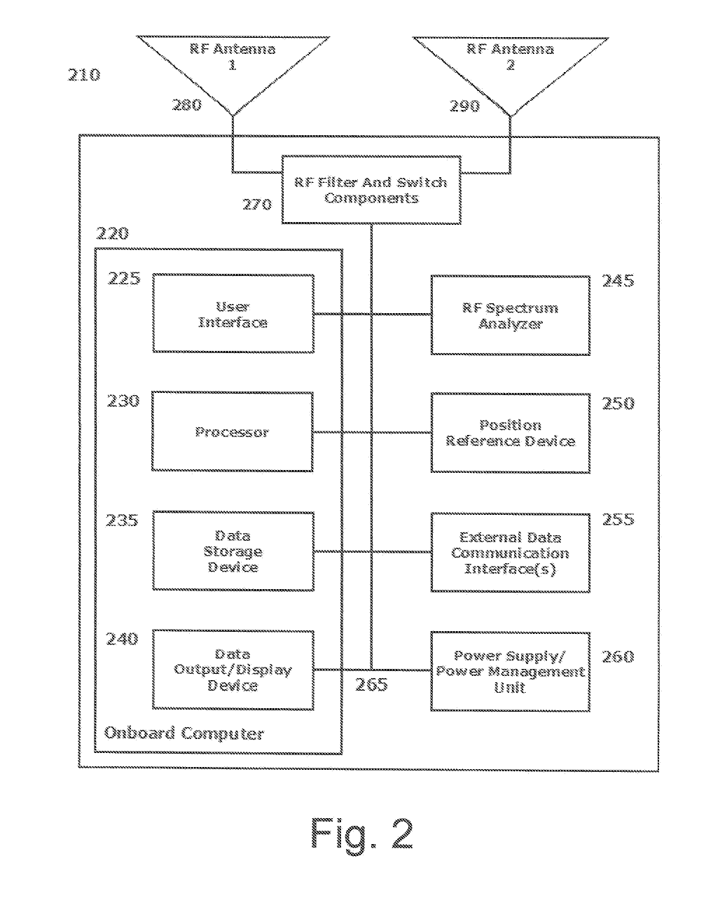

FIG. 2 illustrates a block diagram of an exemplary RSAS 210 for conducting extended duration remote spectrum analysis according to this disclosure. The components of the exemplary RSAS 210 shown in FIG. 2 may be modularized and housed in a rugged case, such as a Pelican® case, to be easily transported anywhere in the world. An alternate rack mount package may be provided for permanent installation. Such an embodiment may be useful for operation at cell sites, permanent Tactical Control Facilities, mobile Tactical Operations Centers and other similar facilities with rack infrastructure.

The RSAS 210 may include one or more RF spectrum analyzers 245, an onboard computer 220 and a power supply and/or power management unit 260. Backhaul and diagnostics for the RSAS 210 may be provided by the processor 230 in the RSAS 210. An objective for the RSAS 210 is to house all of the data acquisition and at least some of the processing capabilities in the RSAS 210 to support remote unattended operation.

The computer 220 in the RSAS 210 may be a low power onboard computer, running an operating system such as, for example, the Linux operating system to manage the data collection and remote operation capabilities of the RSAS 210. The computer 220 may issue commands to the spectrum analyzer 245 to set up the measurement, then collect and store in a data storage device 235 the resulting data.

The computer 220 may include a user interface 225 by which the user may communicate with the RSAS 210. The user interface 225 may be configured as one or more conventional mechanisms that permit a user to input information to the RSAS 210. The user interface 225 may include, for example, an integral or attached keyboard and/or mouse by which a user can enter data into the computer 220 of the RSAS 210. The user interface 220 may be as simple as an ON/OFF switch for the computer 220 and/or the RSAS 210.

The computer 220 in the RSAS 210 may also include one or more local processors 230 for individually operating the RSAS 210 and carrying out the disclosed processing, control and diagnostic functions. Onboard diagnostics and controls may be implemented through the processor 230 with analog and digital I/O ports to allow sensing of key system voltages and temperatures, actuation of switches, control signals for filter tuning, and other services in the RSAS 210. Processor(s) 230 may include at least one conventional processor or microprocessor that interprets and executes instructions to execute the algorithms and make the determinations according to the methods of this disclosure.

The computer 220 of the RSAS 210 may include one or more data storage devices 235. Such data storage devices 235 may be used to store data or operating programs to be used by the RSAS 210, and specifically the processor 230. Data storage device(s) 235 may include a random access memory (RAM) or another type of dynamic storage device that stores information and instructions for execution by processor(s) 230. Data storage device(s) 235 may also include a read-only memory (ROM), which may include a conventional ROM device or another type of static storage device that stores static information and instructions for processor(s) 230. Further, as depicted, the data storage devices 235 may be integral to, or associated with, the computer 220 in the RSAS 210, or may be provided, at least in part, external to, and in wireless communication with, the RSAS 210.

Data files in and from the RSAS 210, whether stored locally in a data storage device 235, or remotely in support of the SDAS (see FIG. 1) may be maintained in a simple, generic ANSI text-based format that is easily imported into other applications, or that can be customized to meet specific application requirements. Each data file may consist of one complete measurement at one instant as specified by a user, or according to a pre=programmed collection scheme. The computer 220 may merge and format data from the spectrum analyzer 245 into a single data file even if the spectrum analyzer 245 makes multiple measurements to obtain the data. The data file may be encrypted according to a processing and/or encryption algorithm, for example, in the processor 230 in order that the RSAS 210 and the data and programs stored therein may not be accessed by unauthorized persons. File transfer may be made via one of the communication paths discussed below over secure FTP so that two layers of encryption protect the data during transmission. Standard FTP may also be supported for applications where data security is not critical. The data may remain encrypted on a local or remote server until accessed by the SDAS. The data files can also be stored in a user-specified format, as appropriate.

The computer 220 in the RSAS 210 may include at least one data output/display device 240 which may be configured as one or more conventional mechanisms that output information locally to the user, including a display or one or more speakers for alerting a user to an operating condition of the RSAS 210. The data output/display device 240 may separately be an output port for connection locally to a printer, a copier, a scanner, a multi-function device, or a remote storage medium, such as a memory in the form, for example, of a magnetic or optical disk with a corresponding disk drive in order that data may be locally downloaded from the RSAS 210. The at least one data output/display device 240 may include at least one indicator provided to provide indications of RSAS 210 operating status including an indication of the active power source, of battery status, of internal DC circuit breaker status, and of other like operating parameters for the RSAS 210.

The RSAS 210 may include at least one RF spectrum analyzer 245 as a central component of the RSAS 210. The heart of the RSAS 210 is the RF spectrum analyzer 245, which can be nearly any COTS portable spectrum analyzer with either GPIB, serial, USB, or Ethernet remote control capability. A prototype RSAS 210 has been tested with a number of commercially-available spectrum analyzers from a number of different sources. In embodiments, the spectrum analyzer 245 may be operated external to the RSAS 210 case, making the system compatible with larger bench top analyzers as well. Since no modification is made to the analyzer, customers may use their existing equipment if desired.

Configuration of the spectrum analyzer 245 may be accomplished via the onboard computer 220 using a configuration script. A user may enter a desired frequency range, channel width, and other measurement parameters via the user interface 225 of the computer 220. The computer 220 may automatically set up the required measurements so that the collected analyzer data corresponds to the user's requested channelization plan. The computer 220 may automatically calculate a number of channels in a desired frequency range and compare with a number of data points per measurement provided by the spectrum analyzer 245. The spectrum analyzer 245 may split the measurement up so that there is one data point for each user channel. This scheme may aid in assuring a highest accuracy in the reporting of spectrum data and simplify comparison of measured data to user databases. The configuration script may be prepared in advance, onsite during deployment, or remotely via network access, and may be changed any time through one or more of the external communication interfaces 255.

The RSAS 210 may include one or more position reference devices 250. Such position reference devices 250 may comprise a GPS receiver for receiving global positioning satellite location information to the RSAS 210, and/or may include an inertial navigation system or other like device that can localize the position of the RSAS 210 for use. When the spectrum analyzer 245 is associated with a position reference device, measurements can be tagged with the geo-location information, including GPS information and time. Alternately, a position reference device 250 may include a USB GPS receiver that can be added to the RSAS 210 to provide GPS time and location data directly to the onboard computer 220 for tagging of measurements. The RSAS 210 can operate without position reference or GPS using the computer 220 onboard clock to timestamp measurements (either according to local time or UTC). Measurements can also be tagged with alternate location identifiers for sensitive deployments to obscure the data origin location. GPS operation may provide an ability to make on-the-move measurements, either for S-COP input from mobile units, or for coverage analysis drive testing.

The RSAS may also capture other information from the spectrum analyzer 245 such as waveform identification of wireless formats or BER data for digital systems, such as APCO P25 systems from instruments having this capability. This may allow simultaneous measuring of signal level and BER. Drive test measurements can be made using GPS spatial averaging techniques according to known methods to average out, for example, fading effects that may otherwise bias mobile signal measurements.

The RSAS 210 may include one or more external data communication interfaces 255 by which the RSAS 210 may communicate with components external to the RSAS 210 including a remote monitoring facility with an SDAS such as that shown, for example, in FIG. 1. External data communication interface(s) 255 may include any mechanism that facilitates direct communication, or communication via a network environment, for the sharing of data collected by, and the results of the processing undertaken by, the RSAS 210. The external data communication interface(s) 255 may include a multi-WAN router that allow the RSAS 210 to use wired Ethernet, Wifi, Cellular, or Satellite backhaul for data gathering and transmission to, for example a remote monitoring facility and/or SDAS. In the event that backhaul is unavailable or undesired, the RSAS 210 may store the data on a high capacity SD card for manual retrieval. A USB port may be provided to allow use of an external USB cellular modem inside the closed case. The RSAS is intended to be compatible with virtually any instrument that can accept control commands via serial or Ethernet connection. The external data communication interfaces 260 may be appropriately configured and include such other mechanisms as may be appropriate for assisting in communications with other devices and/or systems.

Remote operation over a network includes the ability of the RSAS 210 to either store or forward collected data, or to stream data in near real time (depending on network resources). Security is based on SSL using passwords or certificates, and can be enhanced through use of an inline encryption device. The RSAS can be remotely accessed for changing the measurement parameters or to perform diagnostics. The RSAS 210 may also have the ability to automatically report diagnostic information, such as power source, battery status, link failure, instrument failure, and the like. A mobile router may provide automatic least cost or preferred route WAN routing over wired Ethernet, WiFi, up to four different cellular carriers, or satellite. The WiFi link can also be set up as a secure LAN to enable local personnel to wirelessly access and manage the RSAS 210 without touching the RSAS 210 if they are within range, or to link together multiple systems at a single location. A unique capability of the RSAS 210 may be a provision to enable mechanical cycling of the RSAS 210 on-off switch, which allows the system to recover operation after an extended duration power outage, e.g., where an internal battery runs completely down or to be fully powered off and on remotely using an external switched power source.

The RSAS 210 may include a power supply/power management unit 260. The power supply/power management unit 260 may include multiple power supply options, including external auto-sensing worldwide 110-240V, 50/60 Hz AC power, external DC, or internal battery operation. The internal battery may provide integrated UPS protection from power supply interruptions of up to one hour or portable operation for one hour, with longer operation through an external battery as an option. For vehicular use, the system can be operated from 12 or 28 volts DC.

The RSAS 210 may include a plurality of antennas 280,290. The RSAS 210 may be equipped RF filter and switch components 270 as provisions to support switching between the plurality of antennas 280,290 and to provide an internal switched bandpass filter for improved measurement performance when operated at or near co-located transmitter sites. Selection of one or more of the plurality of antennas 280,290 and the tuning of the filter may be controlled by the onboard computer 220 and coordinated with the measurement parameters set in the spectrum analyzer 245. Antenna switching can be used to support direction finding using either directional antennas or Doppler techniques.

All of the various components of the RSAS 210, as depicted in FIG. 2, may be connected by one or more data/control busses 265. These data/control busses 265 may provide wired or wireless communication between the various components of the RSAS 210, as all of those components are housed integrally in, or are otherwise external and connected to, the case for the RSAS 210. All external connections to and from the RSAS 210 may be protected against surge and overload. A Polyphaser® surge protector may be provided for protection of the antenna input, while filtered connectors may be used for network, USB, and AC power inputs. Metal oxide varistors may be provided for the DC power input. An external grounding lug may be provided for connecting the unit ground bus to a site ground.

It should be appreciated that, although depicted in FIG. 2 as an integral unit, the various disclosed elements of the RSAS 210 may be arranged in any combination of sub-systems as individual components or combinations of components, integral to a single unit, or external to, and in wired or wireless communication with the single unit of the RSAS 210. In other words, no specific configuration as an integral unit or as a support unit is to be implied by the depiction in FIG. 2.

It should also be appreciated that the system storage and processing functions described above, given the proper inputs, may be carried out in system hardware circuits, software modules or instructions or firmware, or in varying combinations of these.

For remote deployments, the RSAS 210 may be carried to the deployment location and powered on, and connections made to local power, the monitoring antenna(s), and any hardwired backhaul network. If needed, an external Wifi, cellular or satellite antenna can also be connected if the signal level from the internal antennas is too low. From there, the operation of the RSAS 210 may be fully automatic as previously configured in the computer 220, or as set by remotely accessing the RSAS 210. The cover can be closed and locked, and the RSAS 210, as a unit, can be, for example, chained and locked to a firm object for security.

Cooling for the RSAS may be provided by fans mounted in the case. The RSAS 210 may, therefore, not be weather resistant in operation due to the need for cooling air.

The unique and innovative concepts of the above-described design for the RSAS 210 may include one or more of the following: (1) Use of a low power miniature Linux computer (no hard drive); (2) Use of a multiple WAN router for least cost and redundant path routing; (3)Use of a power management unit for multiple power source and internal UPS functionality; (4) A computer-controlled data acquisition system; (5) Integrated tunable RF pre-selector filter(s); (6) Computer control of RF switches and filters in coordination with spectrum activity measurement; (7) Remotely actuated mechanical on-off for analyzer power pushbutton; and (8) Secure data storage in the device and during transmission.

The SDAS may be used by spectrum management or technical personnel for data reduction and analysis. The desired data files from one or more RSASs may be selected and a choice of data graphical display formats may be made available. Numerical analysis of parameters, such as the percentage of time that a channel power level is above a selected threshold, or the number of channels above a threshold at a particular time can be evaluated. These results may be presented numerically or graphically. Traditional views of spectrum activity, such as channel power versus frequency, channel power versus time, or spectrogram displays can also be created. The SDAS via the RSAS may be able to monitor channels for traffic analysis and derive parameters such as peak busy hour, average call duration, number of calls per hour, etc. In some cases, these values may be approximate depending on a specific set of radio system characteristics.

Data output from an RSAS need not be used with this specific analysis software. This data may be processed using other software including existing packages, or through generic data analysis software.

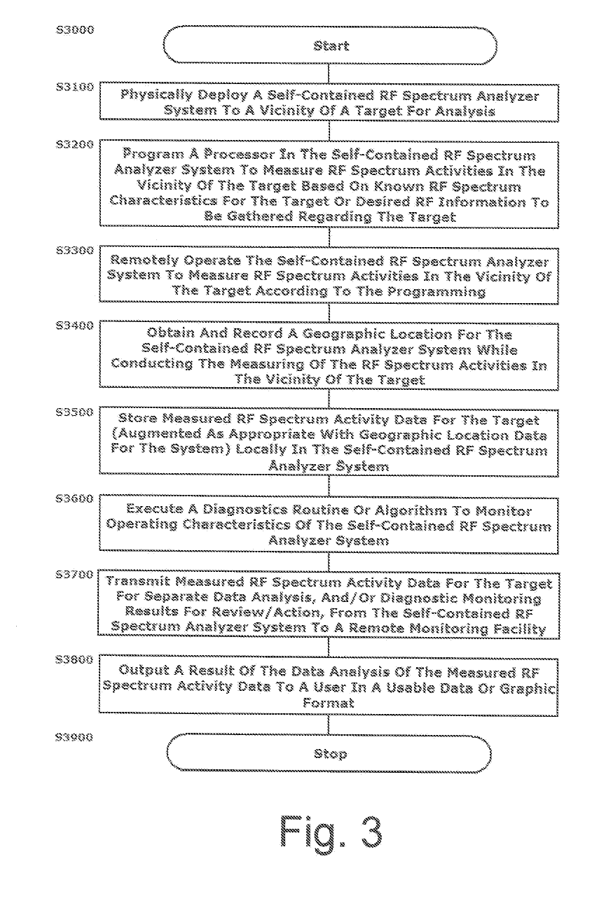

The disclosed embodiments may include a method for conducting extended duration remote spectrum analysis. FIG. 3 illustrates a flowchart of such a method. As shown in FIG. 3, operation of the method commences at Step S3000 and proceeds to Step S3100.

In Step S3100, a self-contained RF spectrum analyzer system (such as that shown in exemplary manner in FIG. 2) may be physically deployed to a vicinity of a target for analysis. The physical deployment of the self-contained RF spectrum analyzer system may be to a fixed location, or in a vehicle, including an air, land, or sea vehicle, for mobile data collection. Generally, when deployed to a fixed location, the self-contained RF spectrum analyzer system may be housed in a ruggedized case to protect the component electronic elements. Otherwise, when deployed in a vehicle for mobile data collection, the self-contained RF spectrum analyzer system may be housed in a ruggedized case, and/or rack mounted. Operation of the method proceeds to Step S3200.

In Step S3200, a processor in the self-contained RF spectrum analyzer system may be programmed to control collection and/or measurement of specific spectrum activities by the RF spectrum analyzer. This programming may occur before the system is deployed, while the system is being deployed, or once the system is deployed in the vicinity of the target for analysis. The collection and/or measurement of specific spectrum activities may be based on known RF characteristics for the target, desired RF information to be gathered regarding the target, or according to other RF spectrum characteristics from or in the vicinity of the target. Operation of the method proceeds to Step S3300.

In Step S3300, once deployed, the self-contained RF spectrum analyzer system may be remotely operated. Such remote operation may be a simple as turning on or off one or more components of the self-contained RF spectrum analyzer. In embodiments, the remote operation may include remote real-time evaluation of operation of the system, RF spectrum measurement data reported from the system, diagnostic information poured from the system, or the like, and sending commands to the processor and the self-contained RF spectrum analyzer system to modify operations of the system. Operation of the method proceeds to Step S3400.

In Step S3400, a geographic location for the self-contained RF spectrum analyzer system may be tracked using one or more position reference devices including, but not limited to, a GPS receiver attached to, or integrated with, the self-contained RF spectrum analyzer system. As one or more individual data elements are detected and measured regarding the RF spectrum activities of or in the vicinity of the target, geographic location reference data for the self-contained RF spectrum analyzer system may be associated with at least some of the one or more individual data elements. This capability is particularly advantageous when the self-contained RF spectrum analyzer system is deployed in a vehicle for mobile operations. Operation of the method proceeds to Step S3500.

In Step S3500, collected and/or measured RF spectrum activity data for the target may be a locally stored in a data storage device or component integrated with, or attached to, the self-contained RF spectrum analyzer system. When appropriate, the collected and/or measured RF spectrum activity data may be supplemented in, for example, a database with geographic location reference data for the self-contained RF spectrum analyzer system, and separately a timecode, to indicate a geographic position of the system when the specific elements of RF spectrum activity data were collected and/or measured. Operation of the method proceeds to Step S3600.

In Step S3600, a processor, or separate microprocessor, in the self-contained RF spectrum analyzer system may executed diagnostics routine or algorithm to monitor an operating condition of one or more of the components of the self-contained RF spectrum analyzer system. The diagnostics routine or algorithm may be executed at random intervals, according to a predetermined schedule (based on time or operations of the system), as directed by a remote operator, or upon sensing some operating characteristic that is currently operating, or is predicted to soon be operating, outside of acceptable range. Presence of such a self-diagnostic capability for the system supports extended duration, remote and unattended operation of the system. Operation of the method proceeds to Step S3700.

In Step 3700, measured RF spectrum activity data for the target may be transmitted from the self-contained RF spectrum analyzer system to a remote facility for further detailed analysis. It should be understood that some level of analysis may be undertaken by the processing and data storage components in the self-contained RF spectrum analyzer system. More detailed analysis, however, as discussed in detail above, may be undertaken at a remote monitoring facility to which raw, or partially-analyzed, data may be transmitted from the self-contained RF spectrum analyzer system. A single remote facility may monitor operations and receive spectrum activity data from a plurality of deployed self-contained RF spectrum analyzer systems. Generally, there will be no crosstalk between deployed self-contained RF spectrum analyzer systems except via the remote monitoring facility. Separately, or as part of a same transmission, the self-contained RF spectrum analyzer system may transmit, as appropriate, diagnostic monitoring results for review and potential action by personnel in the remote monitoring center. Such action may be as simple as executing remote reprogramming to address some potential fault highlighted by the diagnostic monitoring results. Otherwise, such action may be deemed to require support personnel to visit the site where the self-contained RF spectrum analyzer system is deployed in order to make on-site corrective repairs, adjustments or component replacement in order to fully address an actual or potential fault highlighted by the diagnostic monitoring results. Operation of the method proceeds to Step S3800.

In Step S3800, results of the data analysis, whether undertaken by the self-contained RF spectrum analyzer system in the field, or as part of a more robust data analysis effort at the remote monitoring facility, may be output to a user in a form that provides the user a capacity by which to make strategic, tactical, and/or operational decisions for, for example, commencing, augmenting, modifying, or ceasing one or more RF spectrum activities at, or in a vicinity of, the target location. The data may be output for user in any usable data or graphic format that is currently known, or that may be specifically developed to aid decision makers in gaining most beneficial use from the analysis of RF spectrum activities at, or in a vicinity of, one or more target locations. Operation of the method proceeds to Step S3900, where operation of the method ceases.

The disclosed embodiments may include a non-transitory computer-readable medium storing instructions which, when executed by a processor, may cause the processor to execute one or more of the steps of a method as described above.

The above-described exemplary systems and methods reference certain conventional components to provide a brief, general description of a suitable communication and processing environment in which the subject matter of this disclosure may be implemented for familiarity and ease of understanding. Although not required, embodiments of the disclosure may be provided, at least in part, in a form of hardware circuits, firmware or software computer-executable instructions to carry out the specific functions described, such as program modules, being executed by a processor. Generally, program modules include routine programs, objects, components, data structures, and the like that perform particular tasks or implement particular data types.

Those skilled in the art will appreciate that other embodiments of the invention may be practiced in communication network environments with many types of spectrum analysis equipment and components supported by communication equipment and computer system configurations, including many of the system components discussed above.

Embodiments, as indicated, may be practiced in distributed computing environments where tasks are performed by local and remote processing devices that are linked to each other communication links, which are anticipated to be predominantly wireless links. In a distributed computing environment, program modules may be located in both local and remote memory storage devices.

Embodiments within the scope of the present disclosure may also include computer-readable media having stored computer-executable instructions or data structures that can be accessed, read and executed by processing components in one or both of the disclosed self-contained RF spectrum analyzer system, both when being set up and when field deployed, and the disclosed remote monitoring facility. Such computer-readable media can be any available media that can be accessed by a processor, general purpose or special purpose computer in, or in communication with, the self-contained RF spectrum analyzer system such as the RSAS described above. By way of example, and not limitation, such computer-readable media can comprise RAM, ROM, EEPROM, CD-ROM, flash drives, data memory cards or other analog or digital data storage device that can be used to carry or store desired program elements or steps in the form of accessible computer-executable instructions or data structures. When information is transferred or provided over a communications connection, whether wired, wireless, or in some combination of the two, the receiving processor properly views the connection as a computer-readable medium. Thus, any such connection is properly termed a computer-readable medium. Combinations of the above should also be included within the scope of the computer-readable media for the purposes of this disclosure.

Computer-executable instructions include, for example, non-transitory instructions and data that can be executed and accessed respectively to cause the disclosed RSAS or other like system, or a processor therein, to perform certain of the above-specified functions, individually, or in combination. Computer-executable instructions also include program modules that are remotely stored for access by deployed systems to be executed by processors in the deployed systems when those systems are caused to communicate with remote processing components. The exemplary depicted sequence of executable instructions or associated data structures represents one example of a corresponding sequence of acts for implementing the functions described in the steps. Not all steps need to be executed, nor are the steps necessarily executed and depicted sequence.

Although the above description may contain specific details, they should not be construed as limiting the claims in any way. Other configurations of the described embodiments of the disclosed systems and methods are part of the scope of this disclosure. For example, the principles of the disclosure may be applied to each individual user where each user may individually deploy such a system. This enables each user to use the benefits of the disclosure even if any one of the large number of possible applications do not need a specific aspect of the functionality described and depicted in this disclosure. In other words, there may be multiple instances of the components each processing the content in various possible ways. It does not necessarily need to be one system used by all end users. Accordingly, the appended claims and their legal equivalents should only define the disclosure, rather than any specific examples given.

We claim:

1. A deployable radio-frequency spectrum analyzing system unit, comprising:
a radio-frequency spectrum analyzer that measures spectrum activities in a vicinity of the radio-frequency spectrum analyzer;
at least one antenna associated with the radio-frequency spectrum analyzer for receiving radio frequency emissions associated with the spectrum activities in the vicinity of the radio-frequency spectrum analyzer;
a separate processor co-located with the radio-frequency spectrum analyzer that is programmed to control operation of the radio-frequency spectrum analyzer; and
a data storage device co-located with the processor and the radio-frequency spectrum analyzer that stores data on the spectrum activities measured by the radio-frequency spectrum analyzer,
the radio-frequency spectrum analyzer, the at least one antenna, the separate processor and the data storage device being housed in a ruggedized, weather resistant case for field deployment.

2. The system unit of claim 1, further comprising a local power supply by which system components may be powered.

3. The system unit of claim 2, the local power supply being a battery housed in the ruggedized, weather resistant case.

4. The system unit of claim 1, further comprising an external data communication interface configured to transmit the data on the spectrum activities measured by the radio-frequency spectrum analyzer to a remote processing facility.

5. The system unit of claim 4, the external data communication interface being at least one of a WiFi communication connection, a cellular communication connection, a radio communication connection and a satellite communication connection.

6. The system unit of claim 1, further comprising a position reference device housed in the ruggedized, weather resistant case that provides geographic location information for the system.

7. The system unit of claim 6, the position reference device being a Global Positioning Satellite System receiver.

8. The system unit of claim 6, the geographic location information for the system being stored with the data on the spectrum activities measured by the radio-frequency spectrum analyzer to correlate a location of the system with the data on the spectrum activities.

9. The system unit of claim 1, the at least one antenna being a plurality of antennas.

10. The system unit of claim 9, each of the plurality of antennas being selectable to support measuring the spectrum activities by the radio-frequency spectrum analyzer and a direction finding capability for the system.

11. The system unit of claim 1, the separate processor being further programmed to perform a diagnostic routine that assesses an operation status of at least one component of the system.

12. The system unit of claim 1, the separate processor being remotely reprogrammable via a communication link established with the external data communication interface.

13. The system unit of claim 1, the data storage device being a removable data storage device that is user replaceable to facilitate physical data download from the system.

14. A radio-frequency spectrum analyzing system, comprising:
a monitoring facility housing data collection, analysis and processing components; and
at least one deployable radio-frequency spectrum analyzing system unit that includes:
a radio-frequency spectrum analyzer that measures spectrum activities in a vicinity of the radio-frequency spectrum analyzer;
at least one antenna associated with the radio-frequency spectrum analyzer for receiving radio frequency emissions associated with the spectrum activities in the vicinity of the radio-frequency spectrum analyzer;
a separate processor co-located with the radio-frequency spectrum analyzer that is programmed to control operation of the radio-frequency spectrum analyzer;
a data storage device co-located with the processor and the radio-frequency spectrum analyzer that locally stores data on the spectrum activities measured by the radio-frequency spectrum analyzer;
an external data communication interface configured to transmit the data on the spectrum activities measured by the radio-frequency spectrum analyzer to the monitoring facility; and
a ruggedized, weather resistant case housing the radio-frequency spectrum analyzer, the at least one antenna, the separate processor, the data storage device and the external data communication interface,
the monitoring facility communicating with the at least one deployable radio-frequency spectrum analyzing system unit for data exchange, remote reprogramming of the separate processor and operations monitoring of the at least one deployable radio-frequency spectrum analyzing system unit.

15. The system of claim 14, the at least one deployable radio-frequency spectrum analyzing system unit further comprising a local power supply by which system components may be powered, the local power supply being a battery housed in the ruggedized, weather resistant case with the other components.

16. The system of claim 14, the communicating between the monitoring facility and the at least one deployable radio-frequency spectrum analyzing system unit being via at least one of a WiFi communication connection, a cellular communication connection, a radio communication connection and a satellite communication connection.

17. The system of claim 14, the at least one deployable radio-frequency spectrum analyzing system unit further comprising a position reference device housed in the ruggedized, weather resistant case that provides geographic location information for the at least one deployable radio-frequency spectrum analyzing system unit, which the separate processor associates with the data on the spectrum activities measured by the radio-frequency spectrum analyzer to correlate a location of the at least one deployable radio-frequency spectrum analyzing system unit with the data on the spectrum activities.

18. A method for analyzing radio-frequency spectrum activities in a vicinity of a target location, comprising:
housing at least a radio-frequency spectrum analyzer, an antenna, a separate processor, a data storage device, and an external data communication interface in a ruggedized, weather resistant case as deployable radio-frequency spectrum analyzing system unit;
deploying the deployable radio-frequency spectrum analyzing system unit to a vicinity of a spectrum activities target by leaving the deployable radio-frequency spectrum analyzing system unit in the vicinity of the target;
turning the radio-frequency spectrum analyzer and separate processor on, the radio-frequency spectrum analyzer measuring spectrum activities in the vicinity of the target under control of the separate processor and via the antenna;
storing data on the spectrum activities measured by the radio-frequency spectrum analyzer locally in the deployable radio-frequency spectrum analyzing system unit; and
transmitting the data on spectrum activities to a remote processing facility via a communication link supported by the external data communication interface for further processing of the data.

19. The method of claim 18, further comprising powering the deployable radio-frequency spectrum analyzing system unit with a battery housed in the ruggedized, weather resistant case.

20. The method of claim 18, communication link being at least one of a WiFi communication connection, a cellular communication connection, a radio communication connection and a satellite communication connection.

21. The method of claim 18, further comprising:
determining a geographic location for the deployable radio-frequency spectrum analyzing system unit using an integral position reference device housed in the ruggedized, weather resistant case; and
associating the determined geographic location information for the deployable radio-frequency spectrum analyzing system unit with the data on the spectrum activities.
